(19) United States
(12) Patent Application Publication
(10) Pub. No.: US 2007/0161126 A1
(43) Pub. Date: Jul. 12, 2007

(54) Ferroelectric capacitor and method for fabricating the same

(76) Inventors: Shinichiro Hayashi, Osaka (JP); Toru Nasu, Kyoto (JP)

Correspondence Address: MCDERMOTT WILL & EMERY LLP, 600 13TH STREET, N.W., WASHINGTON, DC, 20005-3096, US

(21) Appl. No.: 11/540,752

(22) Filed: Oct. 2, 2006

(30) Foreign Application Priority Data
Jan. 10, 2006 (JP) JP 2006-002094

(51) Int. Cl. H01L 21/00

(52) U.S. Cl. 438/3

(57) ABSTRACT

In a ferroelectric capacitor comprising: a lower electrode; a ferroelectric film formed on the lower electrode; and an upper electrode formed on the ferroelectric film, the coercive voltage of the ferroelectric film is 1.5 V or less and the polarization switching time of the ferroelectric film is 200 ns or less.

### BACKGROUND OF THE INVENTION

(a) Fields of the Inventions

The present invention relates to ferroelectric memory devices using dielectric materials, and to ferroelectric capacitors and their fabrication methods capable of enhancing the speed at which the polarization of a ferroelectric film is reversed.

(b) Description of Related Art

In the development of ferroelectric memory devices, in order to fabricate the devices having stack structures with a large capacity of 256 kbit to 4 Mbit, a significant increase in degree of integration of the devices, that is, miniaturization of the devices is indispensable. Moreover, the devices are required to operate at high speed.

For example, a first conventional example (see, for example, Japanese Laid-open Patent Publication No. H7-99252) proposes the high-speed operation method as described below. In the case where a ferroelectric film made of PZT(PbZrₓTi₁₋ₓO₃) with a ferroelectric crystal structure of ABO₃ (where A and B represent metal) is formed as a ferroelectric film used in a ferroelectric capacitor, a seed layer made of PTO is formed and then a ferroelectric film made of PZT is formed, thereby lowering the Curie temperature Tc. This prevents degradation in polarization switching characteristics of the ferroelectric capacitor and provides high-speed operation of the ferroelectric memory device.

As another example, a second conventional example (see, for example, Japanese Laid-open Patent Publication No. H9-25124 (Japanese Patent No. 3106913)) proposes the high-speed operation method as described below. In the case where a ferroelectric film made of SBT (SrBiTa₂O₉) with a bismuth layer ferroelectric crystal structure is formed as a ferroelectric film used in a ferroelectric capacitor, Sr constituting the ferroelectric film can be substituted partially by Ba to decrease the coercive voltage, or Ta can be substituted partially by Nb to increase remanent polarization. By utilizing them, high-speed operation of the ferroelectric memory device is provided.

### SUMMARY OF THE INVENTION

In the first conventional example, since the Curie temperature Tc of the ferroelectric is lowered, the capacitor operates unstably at high temperatures. This in turn degrades the characteristics of retention or imprint reliabilities thereof. Furthermore, precise composition control is required in order to set the temperature at a desired Curie temperature Tc. Moreover, the process stability is also unstable, and it is still difficult to fully prevent degradation in the stability.

In addition, from a detailed study, the inventors have found that a ferroelectric capacitor fabricated by the method of the first and second conventional examples has degraded polarization switching characteristics. In particular, for the ferroelectric capacitor fabricated by a solution coating method using a spin coating like the second conventional example, the stoichiometric composition thereof is shifted to produce a practical amount of polarization. As a result of this, degradation in polarization switching characteristics is remarkable.

In view of the foregoing, an object of the present invention is to provide a ferroelectric capacitor and its fabrication method for producing a ferroelectric memory device capable of operating at high speed. Another object of the present invention is to provide a ferroelectric capacitor and its fabrication method for producing a ferroelectric memory device capable of operating with stability.

To attain the above object, a ferroelectric capacitor according to a first aspect of the present invention comprises: a lower electrode; a ferroelectric film formed on the lower electrode; and an upper electrode formed on the ferroelectric film, and when the coercive voltage of the ferroelectric film is 1.5 V or less, the polarization switching time of the ferroelectric film is 200 ns or less. With this ferroelectric capacitor, excellent polarization switching characteristics and stable operation can be provided. The ferroelectric film employed in this capacitor has a layered perovskite structure composed of SrBi₂(Ta₁₋ₓNbₓ)₂O₉ (commonly known as SBTN), and the thickness of the ferroelectric film is 120 nm or less.

In the ferroelectric capacitor according to the first aspect of the present invention, when the coercive voltage of the ferroelectric film is 1.0 V or less, the polarization switching time of the ferroelectric film is 100 ns or less. With this ferroelectric capacitor, more excellent polarization switching characteristics and stable operation can be provided. The ferroelectric film employed in this capacitor has a layered perovskite structure composed of SrBi₂(Ta₁₋ₓNbₓ)₂O₉, and the thickness of the ferroelectric film is 80 nm or less.

In the ferroelectric capacitor according to the first aspect of the present invention, when the coercive voltage of the ferroelectric film is 0.6 V or less, the polarization switching time of the ferroelectric film is 20 ns or less. With this ferroelectric capacitor, much more excellent polarization switching characteristics and stable operation can be provided. The ferroelectric film employed in this capacitor has a layered perovskite structure composed of SrBi₂(Ta₁₋ₓNbₓ)₂O₉, and the thickness of the ferroelectric film is 50 nm or less.

A method for fabricating a ferroelectric capacitor according to the first aspect of the present invention is characterized in that a ferroelectric film is formed by an MOCVD method which employs at lease one metal organic material of which main component is one of elements constituting the ferroelectric film. With this method, a thinner ferroelectric film can be provided.

Moreover, the lower and upper electrodes are preferably formed by an MOCVD method which employs at least one metal organic material of which main component is noble metal.

As shown above, the present invention can offer the ferroelectric capacitor which prevents degradation of ferroelectric materials during a semiconductor fabrication process, particularly a decrease in electric properties due to approaches for ferroelectric thickness reduction and low-voltage operation associated with miniaturization of semiconductors, and which conducts excellent high-speed operation and stable operation.

### BRIEF DESCRIPTION OF THE DRAWINGS

FIGS. 1A to 1C are sectional views showing a method for fabricating a ferroelectric capacitor according to a first embodiment of the present invention in the order of its fabrication process steps.

FIGS. 2A and 2B are sectional views showing the method for fabricating a ferroelectric capacitor according to the first embodiment of the present invention in the order of its fabrication process steps.

FIG. 3 is a graph showing the amount of polarization obtained by the ferroelectric capacitor according to the first embodiment of the present invention and the ferroelectric capacitor according to the conventional example.

FIG. 4A is a graph showing the relation between the coercive voltage (V) of a ferroelectric film and the percentage (%) of polarization reversal obtained by the ferroelectric capacitor according to the first embodiment of the present invention. FIG. 4B is a graph showing the relation between the ratio between Ta and Nb that are the B-site metal elements and the coercive voltage obtained by the ferroelectric capacitor with SBTN used for a ferroelectric film according to the first embodiment of the present invention.

FIGS. 5A to 5C are sectional views showing a fabrication method of a ferroelectric capacitor made of SBTN according to a second embodiment of the present invention in the order of its fabrication process steps.

FIGS. 6A and 6B are sectional views showing the fabrication method of a ferroelectric capacitor made of SBTN according to the second embodiment of the present invention in the order of its fabrication process steps.

FIGS. 7A to 7C are sectional views showing a fabrication method of a ferroelectric capacitor made of PZT according to the second embodiment of the present invention in the order of its fabrication process steps.

FIGS. 8A and 8B are sectional views showing the fabrication method of a ferroelectric capacitor made of PZT according to the second embodiment of the present invention in the order of its fabrication process steps.

FIGS. 9A to 9C are sectional views showing a fabrication method of a ferroelectric capacitor made of BLT((Bi,La)₄Ti₃O₁₂) according to the second embodiment of the present invention in the order of its fabrication process steps.

FIGS. 10A and 10B are sectional views showing the fabrication method of a ferroelectric capacitor made of BLT according to the second embodiment of the present invention in the order of its fabrication process steps.

### DETAILED DESCRIPTION OF THE PREFERRED EMBODIMENTS

Hereinafter, embodiments of the present invention will be described with reference to the accompanying drawings.

### First Embodiment

A ferroelectric capacitor and its fabrication method according to a first embodiment of the present invention will be described.

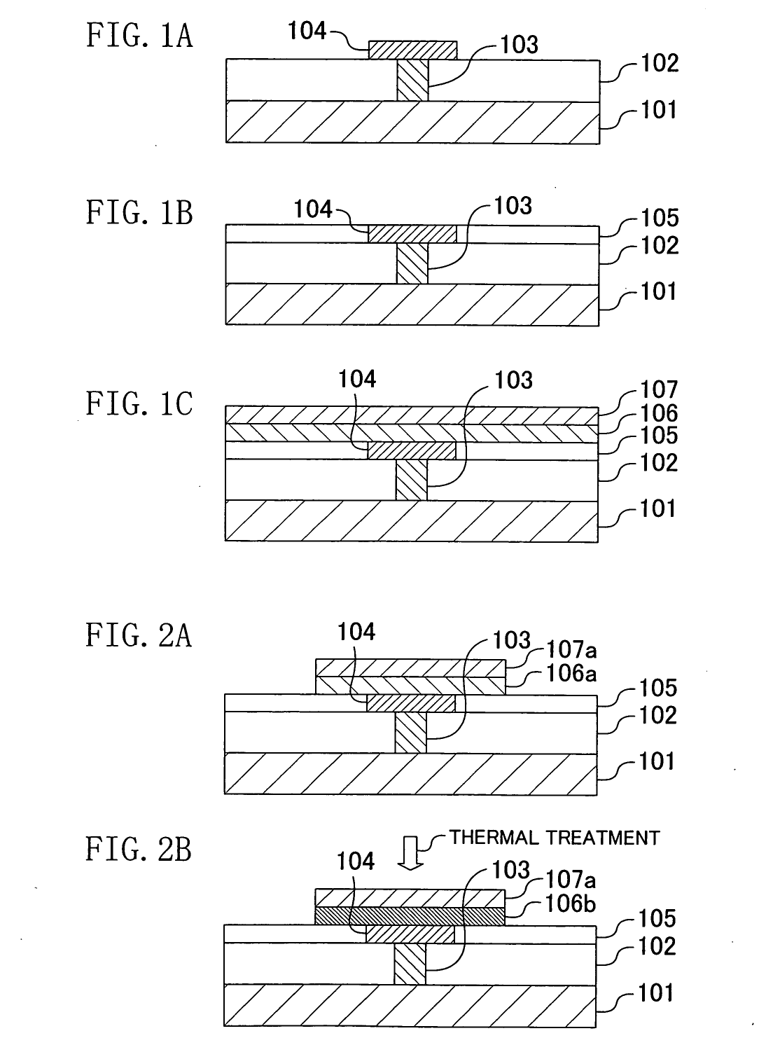

FIGS. 1A to 1C and 2A and 2B are sectional views showing a method for fabricating a ferroelectric capacitor according to the first embodiment of the present invention in the order of its fabrication process steps.

Referring to FIG. 1A, on a semiconductor substrate 101 with memory cell transistors (not shown) and the like formed thereon, a first interlayer insulating film 102 is formed which is made of, for example, a BPSG (SiO₂ with B, P, and the like added therein) film. Subsequently, the first interlayer insulating film 102 is formed with a contact plug 103 of tungsten, polysilicon, or the like whose bottom end reaches the top surface of the semiconductor substrate 101. Then, a lower electrode 104 made by sequentially stacking a barrier layer and a noble metal layer in this order is formed on the first interlayer insulating film 102. The barrier layer is composed of one or more layers selected from, for example, IrO, Ir, TiAlN, and TiN and functions as an oxygen barrier. The bottom surface of the barrier layer is connected to the top end of the contact plug 103. The noble metal layer promotes crystal growth of a ferroelectric film that will be described later. Note that the lower electrode 104 is patterned to cover the first contact plug 103.

In the formation of the lower electrode 104, the noble metal layer coming into contact with the ferroelectric film 106 that will be described later is formed by an MOCVD method using a metal organic material mainly composed of noble metal selected from Pt, Ir, and Ru. Thus, the upper-layer part of the lower electrode 104 has a closely packed crystal structure, which can prevent outward diffusion of ferroelectric-constituting elements. As the noble metal layer located at the upper part of the lower electrode 104, an oxygen-containing composition may be employed. However, if a compound is employed for this layer, it is preferably formed so that the amount of shift from the stoichiometric composition (which is the state in which an actual composition of a compound exactly matches the chemical formula thereof) is within 10%.

Next, as shown in FIG. 1B, on the first interlayer insulating film 102, a buried insulating film made of SiO₂, O₃TEOS, or the like is formed to cover the lower electrode 104, and then CMP is carried out to expose the top surface of the lower electrode 104. Thereby, the buried insulating film 105 surrounding the lower electrode 104 is formed on the first interlayer insulating film 102. Although the lower electrode 104 is buried in the insulating film in the first embodiment, it is not limited to this structure.

As shown in FIG. 1C, a ferroelectric film 106 made of SBTN or the like and a conductive film 107 made of one or more layers selected from Pt, Ir, and IrO are sequentially formed from bottom to top on the lower electrode 104 and the buried insulating film 105. In this formation step, the ferroelectric film 106 is formed by an MOCVD method using a metal organic material mainly composed of elements constituting the film 106. For example, thereafter, a heating treatment may be performed at a temperature at which the ferroelectric film is not crystallized.

The ferroelectric film made of SBTN has a bismuth layer perovskite structure made by alternately stacking a bismuth oxide layer and a perovskite layer, and has a general formula represented by (Bi₂O₂)²⁺(Aₘ₋₁BₘO₃ₘ₊₁)²⁻ (where A is bivalent or trivalent metal, B is quadrivalent or pentavalent metal, and m satisfies 2, 3, 4, or 5), in which A is Sr, B is Ta and Nb, and m=2.

The composition of the ferroelectric film 106, SrₓBi_{y}(Ta_{1-b}Nb_{b})₂O_{5+x+3y/2}, is made so that the amount of shift from the stoichiometric composition is within 10% (0.9≦x≦1, 2≦y≦2.2, 0.5<b≦1). The reason for this is as follows. If the shift amount from the stoichiometric composition is beyond 10%, strain in the crystal of the ferroelectric film becomes large to raise the coercive voltage. This degrades high-speed operation of the ferroelectric capacitor. Furthermore, this hinders creation of a practical amount of polarization (2Pr).

More preferably, if the ferroelectric film 106 has an ABO₃-type composition, for example, if it is composed of PZT (PbZr_{1-b}Ti_{b}O₃)-based ferroelectric, the A-site element is composed to be shifted in the decreasing direction from the stoichiometric composition and to have a shift amount within 10% (Pbₓ(Zr_{1-b}Ti_{b})O₂₊ₓ (0.9≦x≦1, 0.5<b≦1)).

Preferably, if the ferroelectric film 106 is composed of, for example, bismuth layer ferroelectric ((Bi₁₋ₐLaₐ)Bi₃Ti₃O₁₂) structure, the A-site element is composed to be shifted in the decreasing direction from the stoichiometric composition and to have a shift amount within 10%, and the Bi element constituting the Bi-layer structure is composed to be shifted in the increasing direction from the stoichiometric composition and to have a shift amount within 10% ((Bi₁₋ₐLaₐ)ₓBi_{y}Ti₃O_{6+3x/2+3y/2} (0.9≦x≦1, 3≦y≦3.3, 0.5<a≦1)).

As shown in FIG. 2A, the ferroelectric film 106 and the conductive film 107 are patterned to form a capacitor insulating film 106a covering the top surface of the lower electrode 104 and an upper electrode 107a. Although the ferroelectric film 106 and the conductive film 107 are patterned using the same mask in this step, the patterning may be conducted using different masks.

Next, as shown in FIG. 2B, if the capacitor insulating film 106a with an insufficient crystallinity is formed, a thermal treatment may be additionally performed on the film to form the crystallized capacitor insulating film 106b. In the manner described above, a ferroelectric capacitor formed of the lower electrode 104, the capacitor insulating film 106b, and the upper electrode 107a is fabricated. The conductive film 107 is formed by an MOCVD method using a metal organic material mainly composed of noble metal selected from Pt, Ir, and Ru. Thus, the upper electrode 107a has a closely packed crystal structure, which can prevent outward diffusion of ferroelectric-constituting elements. As the noble metal layer contained in the upper electrode 107a, an oxygen-containing composition may be employed. However, if a compound is employed for this layer, it is preferably formed so that the amount of shift from the stoichiometric composition is within 10%. Although not shown, subsequent steps are carried out as follows. For example, a second interlayer insulating film is formed to cover the ferroelectric capacitor, and the second interlayer insulating film is formed with a second contact plug whose bottom end is connected to the top surface of the upper electrode 107a. Then, on the second interlayer insulating film, an interconnect (a bit line) made of an Al/TiN/Ti stacked film is formed whose bottom surface is connected to the top end of the second contact plug.

As described above, with the first embodiment of the present invention, the lower electrode, the capacitor insulating film, and the upper electrode can have good crystalline structures each formed by an MOCVD method. Moreover, since the compositions of the lower electrode, the capacitor insulating film, and the upper electrode become nearly stoichiometric, they can have closely packed structures to prevent outward diffusion of ferroelectric-constituting elements from the capacitor insulating film. Therefore, the occurrence of a degraded layer at the interfaces between the capacitor insulating film and the electrodes can be prevented. From detailed experiments, the inventors have found the following fact. In particular, the solution coating method in the conventional example has the characteristic in that an intentional shift from the stoichiometric composition is generated to create large crystal strain, thereby increasing the amount of polarization, while the ferroelectric film formed by an MOCVD method has a different characteristic from the solution coating method in that the polarization amount increases as the film composition is closer to the stoichiometric composition. That is to say, with the first embodiment, the characteristics which oppose one another in the conventional method, to be more specific, good crystallinity, closely packed structure, and an increased polarization amount can become mutually compatible. As a result of the above, a capacitor insulating film with a thinner thickness and lower-voltage operation can be provided.

Herein, the effects exerted by the first embodiment of the present invention will be described in a concrete manner.

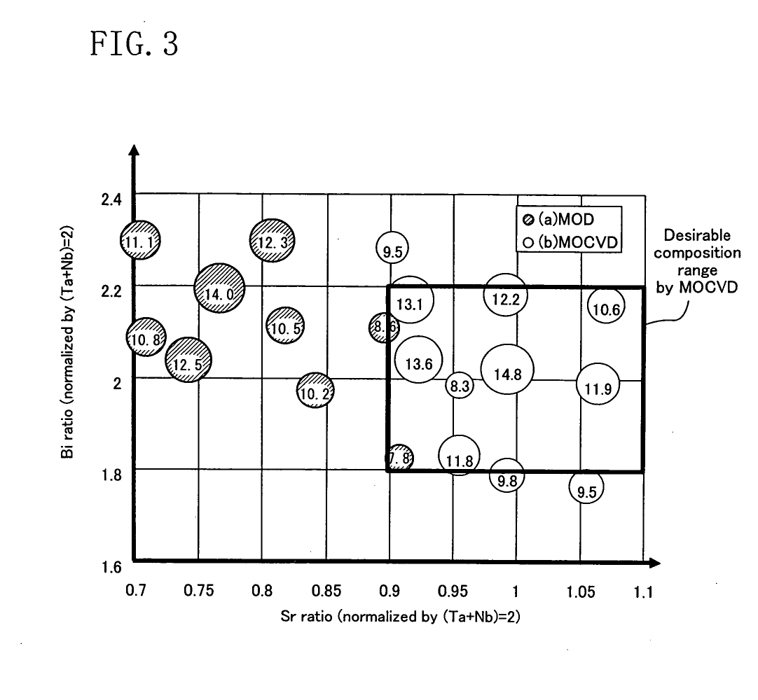

FIG. 3 shows the relation between the amount of polarization (a number in a circle) and the content of the ferroelectric obtained by the ferroelectric capacitor actually fabricated according to the first embodiment and the ferroelectric capacitor fabricated by the solution coating (metal organic decomposition: MOD) method according to the conventional example. In FIG. 3, (a) indicates a sample fabricated by the solution coating method according to the conventional example, while (b) indicates a sample fabricated by the MOCVD method according to the first embodiment. Herein, the lower electrodes of the ferroelectric capacitors of the used samples are made of Pt, and the respective ferroelectric films have a thickness of 100 nm. The composition of each ferroelectric film is measured by a fluorescent X-ray spectrometer, and each polarization amount is measured with a voltage of 1.8 V applied to the ferroelectric capacitor.

Referring to FIG. 3, it is found that in the ferroelectric capacitor of the first embodiment having the ferroelectric film formed by the MOCVD method, the composition with a maximum amount of polarization is shifted to be located around the stoichiometric composition (Sr=1, Bi=2) as compared with the conventional ferroelectric capacitor having the ferroelectric film formed by the MOD method. Further, it is found that in the ferroelectric capacitor according to the first embodiment, the amount of polarization thereof indicates a maximum value. From these facts, the optimum point and the highest value of the polarization amount are contained in the range within which the amount of shift from the stoichiometric composition is within 10%.

As is apparent from the above, there are two conceivable reasons why the amount of polarization increases in the first embodiment. As the first reason, since the ferroelectric film has the composition approaching closer around the stoichiometric composition and also has a closely packed crystal structure with a few number of crystal defects, the number of defects in the ferroelectric becomes fewer than that of the ferroelectric capacitor for comparison made by the different fabrication method. Moreover, the ferroelectric capacitor according to the first embodiment has the electrodes formed by the MOCVD method to provide a closely packed crystal structure. Thus, as the second reason, shift of composition of the ferroelectric film is suppressed at the interfaces between the lower and upper electrodes and the ferroelectric film, and thereby an interface-degraded layer not providing practical ferroelectric properties can be prevented from occurring.

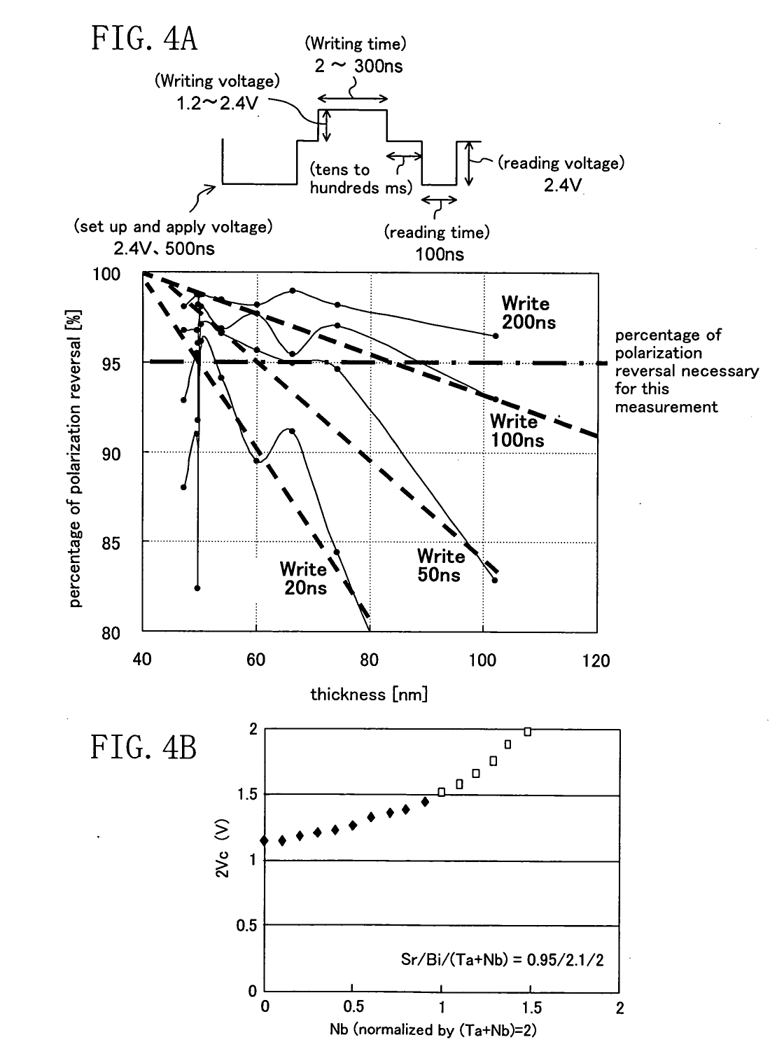

FIG. 4A is a graph showing the relation between the coercive voltage (V) of the ferroelectric film and the percentage (%) of polarization reversal obtained by the ferroelectric capacitor of the first embodiment. In FIG. 4A, the coercive voltage (the voltage required to change biased polarization distribution from the outside of the capacitor) is indicated in terms of the thickness (nm) of the ferroelectric film (in the case of SBTN with a layered perovskite structure satisfying m=2) providing a predetermined coercive voltage.

Herein, the percentage (%) of polarization reversal of each film thickness is measured under the following measurement condition. As shown in FIG. 4A, first, a set-up pulse (2.4 V, 500 ns) is applied to the bit line, and then the writing voltage is changed to 1.2 to 2.4 V Writing operation is performed on the condition of a writing time of 2 to 300 ns, and then the written data is kept for several tens to hundreds of milliseconds. Thereafter, a reading voltage is applied to perform reading operation for a predetermined reading time.

As shown in FIG. 4A, provided that the percentage of polarization reversal necessary for this measurement on the ferroelectric capacitor according to the first embodiment is about 95%, the following result is observed. In the case where writing operation is performed for 20 ns, a coercive voltage of about 0.6 V or less, that is to say, a thickness of SBTN of about 50 nm or less employed as the ferroelectric film in the first embodiment will accomplish 95% that is the target percentage. In the case where writhing operation is performed for 50 ns, a coercive voltage of about 0.7 V or less, that is to say, a thickness of SBTN of about 60 nm or less employed as the ferroelectric film in the first embodiment will accomplish 95% that is the target percentage. In the case where writing operation is performed for 100 ns, a coercive voltage of about 1.0 V or less, that is to say, a thickness of SBTN of about 80 nm or less employed as the ferroelectric film in the first embodiment will accomplish 95% that is the target percentage. In the case where writing operation is performed for 200 ns, a coercive voltage of about 1.5 V or less, that is to say, a thickness of SBTN of about 120 nm or less employed as the ferroelectric film in the first embodiment will accomplish 95% that is the target percentage.

Although not shown, provided that, for example, a PZT film in the present invention is used as a ferroelectric film. In this case, about 95% of a percentage of polarization reversal is obtained when the coercive voltage is set at about 0.7 V or less, that is, the thickness is set at about 30 nm or less, when the coercive voltage is set at about 1.0 V, that is, the thickness is set at about 40 nm or less, or the coercive voltage is set at about 1.5 V, that is, the thickness is set at about 60 nm or less.

Although not shown, provided that, for example, a BLT film in the present invention is used as a ferroelectric film. In this case, about 95% of a percentage of polarization reversal is obtained when the coercive voltage is set at about 0.7 V or less, that is, the thickness is set at about 45 nm or less, when the coercive voltage is set at about 1.0 V, that is, the thickness is set at about 60 nm or less, or the coercive voltage is set at about 1.5 V, that is, the thickness is set at about 40 nm or less.

FIG. 4B is a graph showing the change in coercive voltage relative to the ratio of the B-site metal, which indicates Nb and Ta, in the ferroelectric capacitor employing the SBTN film (where the thickness is 120 nm) according to the first embodiment.

From FIG. 4B, it is found that by setting the Ta amount to satisfy 0.5<Ta≦1, a thickness of the SBTN film of 120 nm can provide a coercive voltage of 1.5 V or less. In this figure, by setting the Ta mount at the same value, for example, a thickness of 50 nm can also have a coercive voltage of 0.6 V or less. Therefore, for any other film thickness, the Ta amount is preferably set at the same value.

It is sufficient that for the PZT film, the ratio of the B-site metal which indicates Zr and Ti is set to satisfy 0.5<Ti≦1, and for the BLT film, the ratio of the A-site metal which indicates Bi and La is set to satisfy 0.5<La≦1.

### Second Embodiment

A second embodiment of the present invention will describe a fabrication method of a ferroelectric capacitor capable of providing an excellent percentage of polarization reversal relative to the thickness of a ferroelectric film as described above in the first embodiment. In the second embodiment, the description is divided according to materials constituting the ferroelectric film.

### —Ferroelectric Film Made of SBTN—

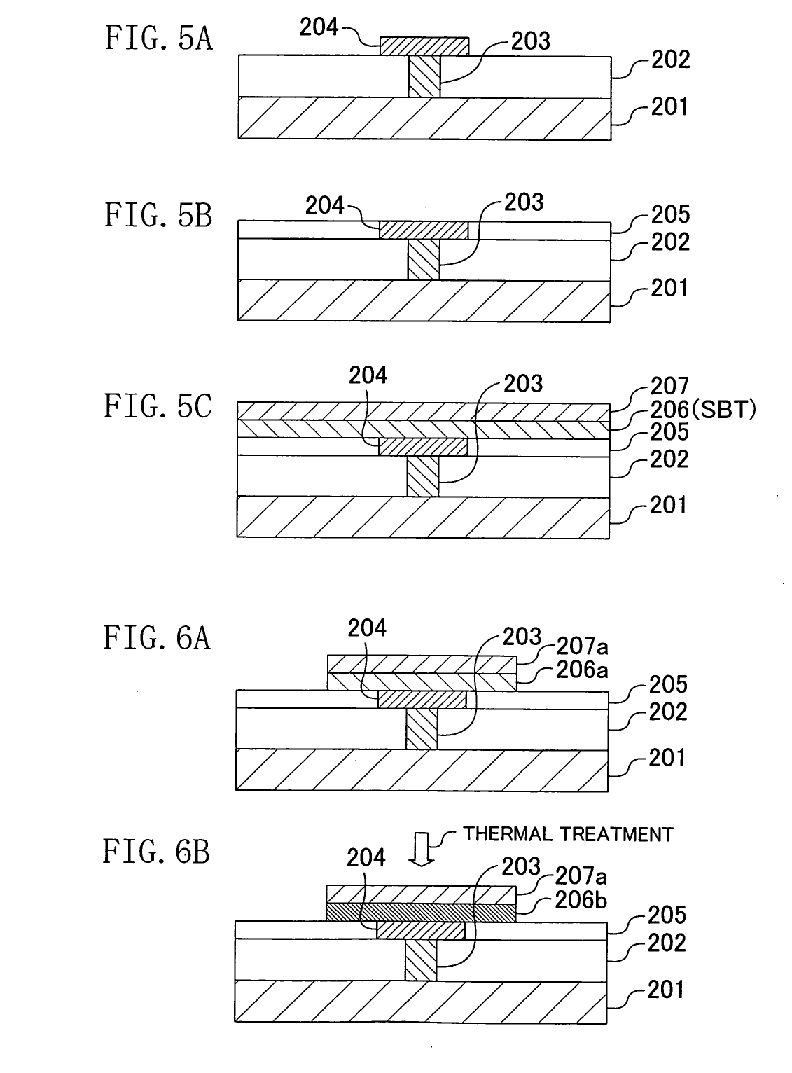

FIGS. 5A to 5C and 6A and 6B are sectional views showing a fabrication method of a ferroelectric capacitor made of SBTN according to the second embodiment of the present invention in the order of its fabrication process steps.

Referring to FIG. 5A, on a semiconductor substrate 201 with memory cell transistors (not shown) and the like formed thereon, a first interlayer insulating film 202 is formed which is made of, for example, a BPSG (SiO₂ with B, P, and the like added therein) film. Subsequently, the first interlayer insulating film 202 is formed with a first contact plug 203 of tungsten, polysilicon, or the like whose bottom end reaches the top surface of the semiconductor substrate 201. Then, a lower electrode 204 made by sequentially stacking a barrier layer and a noble metal layer in this order is formed on the first interlayer insulating film 202. The barrier layer is composed of one or more layers selected from, for example, IrO, Ir, TiAlN, and TiN and functions as an oxygen barrier. The bottom surface of the barrier layer is connected to the top end of the first contact plug 203. The noble metal layer promotes crystal growth of a ferroelectric film that will be described later. Note that the lower electrode 204 is patterned to cover the first contact plug 203.

Next, as shown in FIG. 5B, on the first interlayer insulating film 202, a buried insulating film made of SiO₂, O₃TEOS, or the like is formed to cover the lower electrode 204, and then CMP is carried out to expose the top surface of the lower electrode 204. Thereby, the buried insulating film 205 surrounding the lower electrode 204 is formed on the first interlayer insulating film 202. Although the lower electrode 204 is buried in the insulating film in the second embodiment, it is not limited to this structure.

As shown in FIG. 5C, a ferroelectric film 206 and a conductive film 207 made of one or more layers selected from Pt, Ir, and IrO are sequentially formed from bottom to top on the lower electrode 204 and the buried insulating film 205.

In this formation step, formation of the ferroelectric film 206 is conducted so that by an MOCVD method, the ferroelectric film 206 made of, for example, Sr_{0.95}Bi_{2.1}Ta_{1.8}Nb_{0.2}O_{9.1} is formed on the lower electrode 204 and the buried insulating film 205. If needed, calcination by rapid thermal processing (RTP) is performed for the purpose of producing nuclei serving as base points for crystal growth. Although the temperature for nucleus production differs depending on the type of ferroelectric material, an SBTN material is calcined at about 650° C.

Next, as shown in FIG. 6A, the ferroelectric film 206 and the conductive film 207 are patterned to form a capacitor insulating film 206a covering the top surface of the lower electrode 204 and an upper electrode 207a. Although the ferroelectric film 206 and the conductive film 207 are patterned using the same mask in this step, the patterning may be conducted using different masks.

Next, as shown in FIG. 6B, if the capacitor insulating film 206a with an insufficient crystallinity is formed, a thermal treatment may be additionally performed on the film to form the crystallized capacitor insulating film 206b. Since the target in this step is the capacitor insulating film 206a of SBTN, the thermal treatment is performed at about 650 to 800° C. In the manner described above, a ferroelectric capacitor formed of the lower electrode 204, the capacitor insulating film 206b, and the upper electrode 207a is fabricated. Although not shown, subsequent steps are carried out as follows. For example, a second interlayer insulating film is formed to cover the ferroelectric capacitor, and the second interlayer insulating film is formed with a second contact plug whose bottom end is connected to the top surface of the upper electrode 207a. Then, on the second interlayer insulating film, an interconnect (a bit line) made of an Al/TiN/Ti stacked film is formed whose bottom surface is connected to the top end of the second contact plug.

In the manner described above, by forming the ferroelectric film by an MOCVD method, the ferroelectric film composed closer to the stoichiometric composition and having an increased polarization amount can be provided, that is, good crystallinity and an increased polarization amount can become mutually compatible. As a result of the above, a capacitor insulating film with a small thickness and low-voltage operation can be provided.

In the second embodiment, description has been made of the case of employing the ferroelectric film made of Sr_{0.95}Bi_{2.1}Ta_{1.8}Nb_{0.2}O_{9.1}. Alternatively, it is sufficient that the composition of the ferroelectric film satisfies SrₓBi_{y}(Ta_{1-b}Nb_{b})₂O_{5+x+3y/2} (0.9≦x≦1, 2≦y≦2.2, 0.5<b≦1) and the amount of shift of the stoichiometric composition from SrBi₂(Ta_{1-b}Nb_{b})₂O₉ is within 10%.

### —Ferroelectric Film Made of PZT—

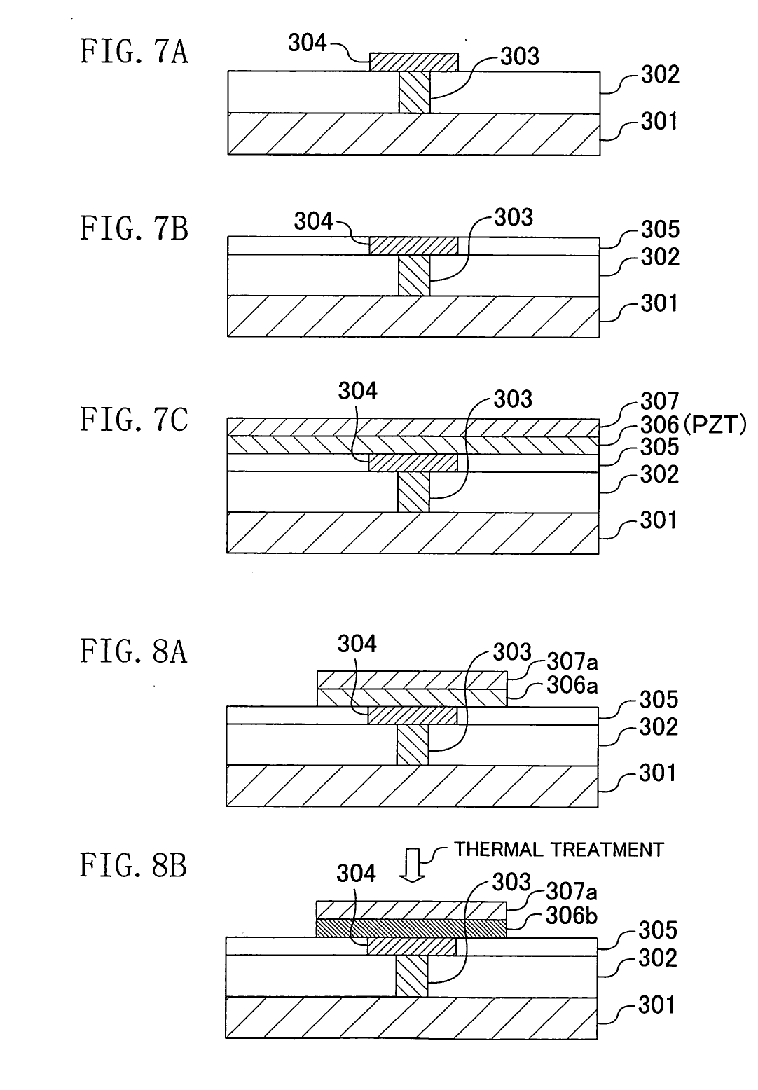

FIGS. 7A to 7C and 8A and 8B are sectional views showing a fabrication method of a ferroelectric capacitor made of PZT according to the second embodiment of the present invention in the order of its fabrication process steps.

Referring to FIG. 7A, on a semiconductor substrate 301 with memory cell transistors (not shown) and the like formed thereon, a first interlayer insulating film 302 is formed which is made of, for example, a BPSG (SiO₂ with B, P, and the like added therein) film. Subsequently, the first interlayer insulating film 302 is formed with a first contact plug 303 of tungsten, polysilicon, or the like whose bottom end reaches the top surface of the semiconductor substrate 301. Then, a lower electrode 304 made by sequentially stacking a barrier layer and a noble metal layer in this order is formed on the first interlayer insulating film 302. The barrier layer is composed of one or more layers selected from, for example, IrO, Ir, TiAlN, and TiN and functions as an oxygen barrier. The bottom surface of the barrier layer is connected to the top end of the first contact plug 303. The noble metal layer promotes crystal growth of a ferroelectric film that will be described later. Note that the lower electrode 304 is patterned to cover the first contact plug 303.

Next, as shown in FIG. 7B, on the first interlayer insulating film 302, a buried insulating film made of SiO₂, O₃TEOS, or the like is formed to cover the lower electrode 304, and then CMP is carried out to expose the top surface of the lower electrode 304. Thereby, the buried insulating film 305 surrounding the lower electrode 304 is formed on the first interlayer insulating film 302. Although the lower electrode 304 is buried in the insulating film in the second embodiment, it is not limited to this structure.

As shown in FIG. 7C, a ferroelectric film 306 and a conductive film 307 made of one or more layers selected from Pt, Ir, and IrO are sequentially formed from bottom to top on the lower electrode 304 and the buried insulating film 305.

In this formation step, formation of the ferroelectric film 306 is conducted so that by an MOCVD method, the ferroelectric film 306 made of Pb_{0.97}Zr_{0.52}Ti_{0.48}O_{2.97} is formed on the lower electrode 304 and the buried insulating film 305. If the ferroelectric film 306 with an insufficient crystallinity is formed, a thermal treatment may be additionally performed on the film to form the crystallized ferroelectric film. If needed, calcination by rapid thermal processing (RTP) is performed for the purpose of producing nuclei serving as base points for crystal growth. Although the temperature for nucleus production differs depending on the type of ferroelectric material, a PZT material is calcined at about 450° C.

Next, as shown in FIG. 8A, the ferroelectric film 306 and the conductive film 307 are patterned to form a capacitor insulating film 306a covering the top surface of the lower electrode 304 and an upper electrode 307a. Although the ferroelectric film 306 and the conductive film 307 are patterned using the same mask in this step, the patterning may be conducted using different masks.

Next, as shown in FIG. 8B, if the capacitor insulating film 306a with an insufficient crystallinity is formed, a thermal treatment may be additionally performed on the film to form the crystallized capacitor insulating film 306b. Since the target in this step is the capacitor insulating film 306a of PZT, the thermal treatment is performed at about 450 to 650° C. In the manner described above, a ferroelectric capacitor formed of the lower electrode 304, the capacitor insulating film 306b, and the upper electrode 307a is fabricated. Although not shown, subsequent steps are carried out as follows. For example, a second interlayer insulating film is formed to cover the ferroelectric capacitor, and the second interlayer insulating film is formed with a second contact plug whose bottom end is connected to the top surface of the upper electrode 307a. Then, on the second interlayer insulating film, an interconnect (a bit line) made of an Al/TiN/Ti stacked film is formed whose bottom surface is connected to the top end of the second contact plug.

In the manner described above, by the ferroelectric film formed by an MOCVD method, the ferroelectric film composed closer to the stoichiometric composition and having an increased polarization amount can be provided, that is, good crystallinity and an increased polarization amount can become mutually compatible. As a result of the above, a capacitor insulating film with a small thickness and low-voltage operation can be provided.

In the second embodiment, description has been made of the case of employing the ferroelectric film made of Pb_{0.97}Zr_{0.52}Ti_{0.48}O_{2.97}. However, the film composition is not limited to this, and any ferroelectric film satisfying Pbₓ(Zr_{1-b}Ti_{b})O₂₊ₓ (0.9≦x≦1, 0.5<b≦1) Pb(Zr_{1-b}Ti_{b})O₃ may be employed.

### —Ferroelectric Film Made of BLT—

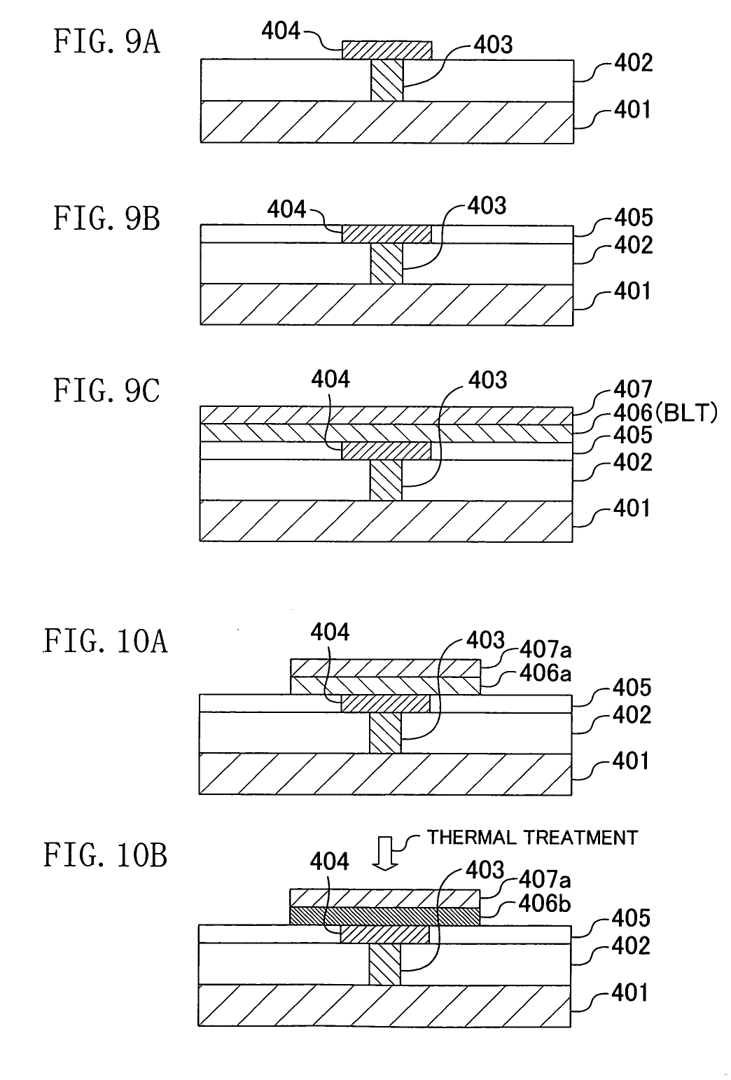

FIGS. 9A to 9C and 10A and 10B are sectional views showing a fabrication method of a ferroelectric capacitor made of BLT according to the second embodiment of the present invention in the order of its fabrication process steps.

Referring to FIG. 9A, on a semiconductor substrate 401 with memory cell transistors (not shown) and the like formed thereon, a first interlayer insulating film 402 is formed which is made of, for example, a BPSG (SiO₂ with B, P, and the like added therein) film. Subsequently, the first interlayer insulating film 402 is formed with a first contact plug 403 of tungsten, polysilicon, or the like whose bottom end reaches the top surface of the semiconductor substrate 401. Then, a lower electrode 404 made by sequentially stacking a barrier layer and a noble metal layer in this order is formed on the first interlayer insulating film 402. The barrier layer is composed of one or more layers selected from, for example, IrO, Ir, TiAlN, and TiN and functions as an oxygen barrier. The bottom surface of the barrier layer is connected to the top end of the first contact plug 403. The noble metal layer promotes crystal growth of a ferroelectric film that will be described later. Note that the lower electrode 404 is patterned to cover the first contact plug 403.

Next, as shown in FIG. 9B, on the first interlayer insulating film 402, a buried insulating film made of SiO₂, O₃TEOS, or the like is formed to cover the lower electrode 404, and then CMP is carried out to expose the top surface of the lower electrode 404. Thereby, the buried insulating film 405 surrounding the lower electrode 404 is formed on the first interlayer insulating film 402. Although the lower electrode 404 is buried in the insulating film in the second embodiment, it is not limited to this structure.

As shown in FIG. 9C, a ferroelectric film 406 and a conductive film 407 made of one or more layers selected from Pt and Ir are sequentially formed from bottom to top on the lower electrode 404 and the buried insulating film 405.

In this formation step, formation of the ferroelectric film 406 is conducted so that by an MOCVD method, the ferroelectric film 406 made of (Bi_{0.2}La_{0.8})_{0.96}Bi_{3.1}Ti₃O_{12.09} is formed on the lower electrode 404 and the buried insulating film 405. If the ferroelectric film 406 with an insufficient crystallinity is formed, a thermal treatment may be additionally performed on the film to form the crystallized ferroelectric film. If needed, calcination by rapid thermal processing (RTP) is performed for the purpose of producing nuclei serving as base points for crystal growth. Although the temperature for nucleus production differs depending on the type of ferroelectric material, a BLT material is calcined at about 500° C.

Next, as shown in FIG. 10A, the ferroelectric film 406 and the conductive film 407 are patterned to form a capacitor insulating film 406a covering the top surface of the lower electrode 404 and an upper electrode 407a. Although the ferroelectric film 406 and the conductive film 407 are patterned using the same mask in this step, the patterning may be conducted using different masks.

Next, as shown in FIG. 10B, if the capacitor insulating film 406a with an insufficient crystallinity is formed, a thermal treatment may be additionally performed on the film to form the crystallized ferroelectric film 406b. Since the target in this step is the ferroelectric film 406a of BLT, the thermal treatment is performed at about 500 to 700° C. In the manner described above, a ferroelectric capacitor formed of the lower electrode 404, the capacitor insulating film 406b, and the upper electrode 407a is fabricated. Although not shown, subsequent steps are carried out as follows. For example, a second interlayer insulating film is formed to cover the ferroelectric capacitor, and the second interlayer insulating film is formed with a second contact plug whose bottom end is connected to the top surface of the upper electrode 407a. Then, on the second interlayer insulating film, an interconnect (a bit line) made of an Al/TiN/Ti stacked film is formed whose bottom surface is connected to the top end of the second contact plug.

In the manner described above, by the ferroelectric film formed by an MOCVD method, the ferroelectric film composed closer to the stoichiometric composition and having an increased polarization amount can be provided, that is, good crystallinity and an increased polarization amount can become mutually compatible. As a result of the above, a capacitor insulating film with a small thickness and low-voltage operation can be provided.

In the second embodiment, description has been made of the case of employing the ferroelectric film made of (Bi_{0.2}La_{0.8})_{0.96}Bi_{3.1}Ti₃O_{12.09}. However, the film composition is not limited to this, and it is sufficient that the composition is (Bi₁₋ₐLaₐ)ₓBi_{y}Ti₃O_{6+3x/2+3y/2} (0.9≦x≦1, 3≦y≦3.3, 0.5<a≦1) whose amount of shift from the stoichiometric composition is within 10%.

In the first and second embodiments, description has been made of the structure in which the lower electrode serves as a capacitance definition unit, that is, the lower electrode is smaller than the upper electrode. Alternatively, it is acceptable that the capacitor has the structure in which the upper electrode serves as a capacitance definition unit. In addition, in order to prevent degradation of the ferroelectric film due to hydrogen, the ferroelectric capacitor may be designed to be surrounded by a hydrogen barrier film, that is, for example, the ferroelectric capacitor may be designed so that a first hydrogen barrier film (SiN, SiON, TiAlO, Al₂O₃) formed below the ferroelectric capacitor and a second hydrogen barrier film (SiN, SiON, TiAlO, Al₂O₃) formed to cover the upper portion of the ferroelectric capacitor cover the left, right, top and bottom of the ferroelectric capacitor.

In the embodiments described above, description has been made of the case where the ferroelectric film is formed without metal doping, but this formation is not limited to the above examples. Even though doping with La, Ca, or the like is carried out to attain the characteristics or reliability of the ferroelectric capacitor, this doping has no influence on the effects of the present invention.

The present invention is useful for a ferroelectric capacitor with a ferroelectric film used as a capacitor insulating film and a ferroelectric memory device using the film.

What is claimed is:

1. A ferroelectric capacitor comprising: a lower electrode; a ferroelectric film formed on the lower electrode; and an upper electrode formed on the ferroelectric film,
wherein the coercive voltage of the ferroelectric film is 1.5 V or less, and the polarization switching time of the ferroelectric film is 200 ns or less.

2. The capacitor of claim 1,
wherein the ferroelectric film has a bismuth layer perovskite structure made by alternately stacking a bismuth oxide layer and a perovskite layer,
the ferroelectric film has a general formula represented by
(Bi₂O₂)²⁺(Aₘ₋₁BₘO₃ₘ₊₁)²⁻
(where A represents bivalent or trivalent metal, B represents quadrivalent or pentavalent metal, and m satisfies 2, 3, 4, or 5), and
in the case where A represents Sr, B represents Ta and Nb, and m=2, the ferroelectric film has a thickness of 120 nm or less.

3. The capacitor of claim 1,
wherein the coercive voltage of the ferroelectric film is 1.0 V or less, and the polarization switching time of the ferroelectric film is 100 ns or less.

4. The capacitor of claim 3,
wherein the ferroelectric film has a bismuth layer perovskite structure made by alternately stacking a bismuth oxide layer and a perovskite layer,
the ferroelectric film has a general formula represented by
(Bi₂O₂)²⁺(Aₘ₋₁BₘO₃ₘ₊₁)²⁻
(where A represents bivalent or trivalent metal, B represents quadrivalent or pentavalent metal, and m satisfies 2, 3, 4, or 5), and
in the case where A represents Sr, B represents Ta and Nb, and m=2, the ferroelectric film has a thickness of 80 nm or less.

5. The capacitor of claim 1,
wherein the coercive voltage of the ferroelectric film is 0.6 V or less, and the polarization switching time of the ferroelectric film is 20 ns or less.

6. The capacitor of claim 5,
wherein the ferroelectric film has a bismuth layer perovskite structure made by alternately stacking a bismuth oxide layer and a perovskite layer,
the ferroelectric film has a general formula represented by
(Bi₂O₂)²⁺(Aₘ₋₁BₘO₃ₘ₊₁)²⁻
(where A represents bivalent or trivalent metal, B represents quadrivalent or pentavalent metal, and m satisfies 2, 3, 4, or 5), and
in the case where A represents Sr, B represents Ta and Nb, and m=2, the ferroelectric film has a thickness of 50 nm or less.

7. The capacitor of claim 1,
wherein the ferroelectric film has a composition in which the amount of shift from the stoichiometric composition is within 10%.

8. The capacitor of claim 7,
wherein the stoichiometric composition is SrBi₂(Ta_{1-b}Nb_{b})₂O₉, and
the composition of the ferroelectric film is SrₓBi_{y}(Ta_{1-b}Nb_{b})₂O_{5+x+3y/2} (0.9≦x≦1, 2≦y≦2.2, 0.5<b≦1).

9. A method for fabricating a ferroelectric capacitor comprising: a lower electrode; a ferroelectric film formed on the lower electrode; and an upper electrode formed on the ferroelectric film,
wherein the ferroelectric film is formed by an MOCVD method which employs at least one metal organic material of which main component is one of elements constituting the ferroelectric film, and
the coercive voltage of the ferroelectric film is 1.5 V or less, and the polarization switching time of the ferroelectric film is 200 ns or less.

10. The method of claim 9,
wherein the lower electrode is formed by an MOCVD method which employs at least one metal organic material of which main component is noble metal, and
the upper electrode is formed by an MOCVD method which employs at least one metal organic material of which main component is noble metal.
